(19) United States
(12) Patent Application Publication
(10) Pub. No.: US 2011/0014394 A1
(43) Pub. Date: Jan. 20, 2011

(54) FILM DEPOSITING APPARATUS AND METHOD

(76) Inventors: Takamichi Fujii, Kanagawa (JP); Takami Arakawa, Kanagawa (JP); Yasukazu Nihei, Kanagawa (JP)

Correspondence Address: BIRCH STEWART KOLASCH & BIRCH, PO BOX 747, FALLS CHURCH, VA, 22040-0747, US

(21) Appl. No.: 12/667,429

(22) PCT Filed: Jul. 29, 2009
(86) PCT No.: PCT/JP2009/063829

§ 371 Date: Dec. 31, 2009

(30) Foreign Application Priority Data
Jul. 31, 2008 (JP) 2008-197939

(51) Int. Cl. C23C 16/50; C23C 16/00

(52) U.S. Cl. 427/569; 118/723 R

(57) ABSTRACT

A film depositing apparatus comprises: a vacuum vessel; an evacuating unit for evacuating the interior of the vacuum vessel; a gas supply source for supplying the vacuum vessel with gases necessary for film deposition; a backing plate that is placed within the vacuum vessel for holding a target formed by sintering; a substrate holder for holding a deposition substrate within the vacuum vessel in a face-to-face relation with the backing plate; and a power supply unit for supplying electric power between the backing plate and the substrate holder to generate a plasma within the vacuum vessel, wherein the backing plate has a smaller thermal expansion coefficient than that of the target which has a sinter density of at least 95%, the sinter density representing the ratio of the actual weight of a sintered form of the target to its theoretical weight.

### TECHNICAL FIELD

The present invention relates to an apparatus and a method for film deposition, in particular, an apparatus and a method for depositing films by plasma-assisted vapor-phase deposition techniques.

### BACKGROUND ART

It is known to deposit a piezoelectric film and other thin films by vapor-phase deposition techniques such as sputtering. In sputtering, plasma ions, such as Ar ions, of high energy that are generated by plasma discharge in high vacuum are allowed to strike a target so that the constituent elements of the target are released and deposited on a surface of a substrate.

If high deposition rate is to be obtained in a film depositing apparatus that implements the sputtering method, it is generally required that more electric power be applied within a vacuum vessel where deposition is done.

However, if a backing plate (target holder) that holds a target in the film depositing apparatus has a greater thermal expansion coefficient than the target, the more electric power that is applied within the vacuum vessel, the hotter the target and the backing plate, with the result that the backing plate expands more than the target to cause cracking in the target.

This problem has been particularly noticeable in the case where the film depositing apparatus has a copper-made backing plate and uses a lead zirconate titanate (PZT) target.

Thus, it is extremely difficult to form a film of good quality at high deposition rate in the film depositing apparatus that implements the sputtering process.

To deal with this problem and to obtain films of good quality, Patent Document 1 discloses the use of a backing plate molded monolithically to have a hollow structure in the interior of which a cooling water channel is provided; the backing plate is not thicker than the conventional type and yet it is improved in strength and can realize an adequate cooling efficiency.

In addition, Patent Document 2 discloses the use of a target designed to form ferroelectric films with extremely small variations in the Pb content, namely, films of good quality; the target uses metallic Pb as a matrix and has such a structure that at least one type of particles that is selected from among metallic Ti particles, metallic Zr particles, metallic La particles, oxidized Ti particles, oxidized Zr particles and oxidized La particles and which has a maximum particle size of no more than 50 μm are uniformly dispersed in the metallic Pb matrix.

Further in addition, Patent Document 3 discloses the use of a ferroelectric thin film forming target that is designed to form ferroelectric films with extremely small variations in the Pb content, namely, films of good quality; the target is made of a sintered body of lead zirconate titanate in which Pb, Zr and Ti are present in such proportions that the molar ratio of Pb/(Zr+Ti) is in the range of 1.01 to 1.30, the excess Pb being composed of Pb3O4 based lead oxide.

### CITATION LIST

### [PATENT LITERATURE]

[PTL 1] JP 9-78233 A
[PTL 2] JP 10-317131 A
[PTL 3] JP 11-001367 A

### SUMMARY OF THE INVENTION

### Technical Problems

The backing plate disclosed in Patent Document 1 features high strength and cooling efficiency to realize the formation of films of good quality; nevertheless, the structure of the backing plate is so complex in itself that the production cost will increase.

In addition, the target disclosed in Patent Document 2 is protected against variations in the Pb content and the occurrence of particles and thus enables the formation of films of good quality; nevertheless, the document takes no interest whatsoever in forming films of quality at high enough deposition rate.

Further in addition, the target disclosed in Patent Document 3 also enables consistent production of films of good quality (dielectric thin films); nevertheless, the document takes no interest whatsoever in forming films of good quality at high enough deposition rate.

An object, therefore, of the present invention is to solve the problems with the aforementioned prior art by providing an apparatus and a method for film deposition that can form thin films of good quality at high enough deposition rate without causing cracks in a target held on a backing plate and without increasing the equipment cost.

### SOLUTION TO THE PROBLEMS

A film depositing apparatus according to the present invention comprises: a vacuum vessel; an evacuating means for evacuating the interior of the vacuum vessel; a gas supply source for supplying the vacuum vessel with gases necessary for film deposition; a backing plate that is placed within the vacuum vessel for holding a target formed by sintering; a substrate holder for holding a deposition substrate within the vacuum vessel in a face-to-face relation with the backing plate; and a power supply means for supplying electric power between the backing plate and the substrate holder to generate a plasma within the vacuum vessel, wherein the backing plate has a smaller thermal expansion coefficient than that of the target which has a sinter density of at least 95%, the sinter density representing the ratio of the actual weight of a sintered form of the target to its theoretical weight.

A film depositing method according to the present invention comprises the steps of: holding a target on a backing plate that is placed within a vacuum vessel and which has a smaller thermal expansion coefficient than that of a target which has a sinter density of at least 95%, the sinter density representing the ratio of the actual weight of a sintered form of the target to its theoretical weight; placing a deposition substrate held on a substrate holder within the vacuum vessel in a face-to-face relation with the backing plate; and supplying electric power between the backing plate and the substrate holder, with gases necessary for film deposition being supplied into the vacuum vessel, so as to generate a plasma within the vacuum vessel.

### ADVANTAGEOUS EFFECTS OF THE INVENTION

According to the apparatus and method of the present invention for film deposition, thin films of satisfactory quality can be deposited at high enough deposition rate while ensuring that the target held on a backing plate will not be cracked or otherwise damaged.

### BRIEF DESCRIPTION OF THE DRAWING

FIG. 1 is a sectional view showing in concept the structure of a film depositing apparatus according to an embodiment of the present invention.

### DESCRIPTION OF EMBODIMENTS

On the following pages, the film deposition apparatus and method of the present invention are described in detail with reference to the preferred embodiment shown in the accompanying drawing.

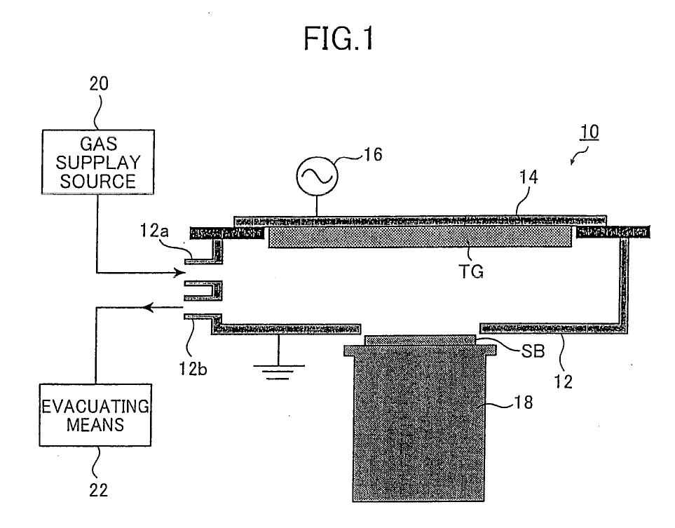

FIG. 1 shows the structure of a film depositing apparatus generally indicated at 10 according to an embodiment of the present invention.

On the following pages, a film depositing apparatus that deposits a piezoelectric film as a thin layer and which produces a piezoelectric device as a thin-film device that uses the thin layer is described as a typical example but it should be noted that the present invention is by no means limited to this particular case.

As shown in FIG. 1, the film depositing apparatus 10 has a vacuum vessel 12 which has a backing plate (target holding member) 14 placed on its ceiling portion. The backing plate 14 not only holds a sputter target material TG but also functions as a cathode for generating a plasma within the vacuum vessel 12. The backing plate 14 is connected to a RF power supply 16. Beneath the area of the vacuum vessel 12 in a face-to-face relation with the backing plate 14, there is provided a platform (substrate holder) 18 for supporting a substrate SB on which a thin layer is to be formed from the constituents of the target material TG.

The vacuum vessel 12 is a highly airtight vessel that is formed of iron, stainless steel, aluminum or any other materials that can maintain a predetermined degree of vacuum required for sputtering; the vacuum vessel 12 is electrically grounded and equipped with a gas supply pipe 12a for supplying the vacuum vessel 12 with the gases necessary for film deposition and a gas exhaust pipe 12b for discharging the gases from the interior of the vacuum vessel 12.

The vacuum vessel 12 may be of various types including a vacuum chamber, a bell jar, and a vacuum tank that are employed in the sputter apparatus.

Gases to be introduced into the vacuum vessel 12 through the gas supply pipe 12a may include argon (Ar), as well as a mixture of argon (Ar) and oxygen (O2).

The gas supply pipe 12a is connected to a gas supply source 20.

The gas exhaust pipe 12b is connected to an evacuating means 22 such as a vacuum pump for discharging gases out of the vacuum vessel 12 so that a predetermined degree of vacuum is created therein and maintained during film deposition.

The RF power supply 16 is for supplying the backing plate 14 with a sufficient amount of RF power (negative RF waves) to form a plasma of Ar and other gases that have been introduced into the vacuum vessel 12; one end of the RF power supply 16 is connected to the backing plate 14 while the other end, although not shown, is electrically grounded. Note that the RF power to be fed to the backing plate 14 by the RF power supply 16 is not particularly limited and may be exemplified by RF power of 13.65 MHz with a maximum output of 5 kW or 1 kW. The backing plate 14 may also be supplied with RF power having a RF output of 1 kW to 10 kW at frequencies of 50 kHz to 2 MHz, 27.12 MHz, 40.68 MHz, and 60 MHz.

The platform 18 is for supporting the bottom of the substrate SB so that it is held within the vacuum vessel 12 at a position in a face-to-face relation with the backing plate 14.

The platform 18 is equipped with a heater (not shown) for heating the substrate SB to a predetermined temperature and maintaining it during film deposition on the substrate SB. The size of the substrate SB to be mounted on the platform 18 is not particularly limited and it may be a circular substrate with a diameter of 6 inches or a diameter of 5 or 8 inches; alternatively, it may be a square substrate 5 cm on all sides.

Note that the substrate SB is electrically insulated from the vacuum vessel 12 and the platform 18 and that the substrate SB is supplied with a predetermined voltage.

The backing plate 14 is a cathode electrode in plate form. It also serves to hold on its surface the target material TG whose composition is determined by the composition of a thin layer to be deposited; the backing plate 14, being electrically insulated from any other components of the vacuum vessel 12, is provided in the upper part of the interior of the vacuum vessel 12 and connected to the RF power supply 16.

The backing plate 14, when supplied with RF power (negative RF waves) from the RF power supply 16, undergoes an electric discharge to form a plasma of Ar and other gases that have been introduced into the vacuum vessel 12, whereupon Ar ions and other positive ions are generated.

Hence, the backing plate 14 may also be called a plasma electrode.

The thus generated positive ions sputter the target material TG held on the backing plate 14. The constituent elements in the sputtered target material TG are released from the target material TG and deposited, in either a neutral or ionized state, on the substrate SB placed in a face-to-face relation with the backing plate 14. This is how a plasma space containing positive ions such as Ar ions as well as the constituent elements of the target material TG and their ions is formed between the backing plate 14 within the vacuum vessel 12 and the substrate SB held on the platform 18.

If the sinter density of the target material TG is less than 95%, the target material TG has such a coarse structure that the sputter rate will decrease; in addition, the internal voids lead to poor heat conduction and, what is more, cooling from the backing plate 14 becomes inadequate and if the surface of the target material TG is heated under this condition, arcing may occur. Hence, the sinter density of the target material TG is preferably at least 95%, more preferably at least 98%. The sinter density may even exceed 100%.

Note that the sinter density as used herein refers to a numerical value that represents the ratio of the actual weight of a sintered form of the target material TG to its theoretical weight. The sinter density shall have the same meaning in all of its appearances in the following description.

The backing plate 14 has a smaller thermal expansion coefficient than the target material TG characterized above. Hence, even if more electric power is supplied into the vacuum vessel 12 in order to improve the deposition rate, there will be no fear that the backing plate 14 expands so excessively as to cause cracking in the target material TG, which has been a common phenomenon in the prior art.

Note also that in the embodiment under consideration, the backing plate 14 is preferably molybdenum-based and, more preferably, it has a thickness not smaller than 5 mm but not greater than 30 mm since this assures adequate rigidity and high cooling efficiency.

On the following pages, the method of film deposition using the film depositing apparatus 10 is described.

First, the sputter target material TG is mounted and held on the backing plate 14 and the substrate SB is then mounted and held on the platform 18.

Here, the target material TG to be used has a sinter density of at least 95%, preferably at least 98% for the reason that this assures crack resistance and ease in handling.

It is also preferred that the target material TG is a material suitable for piezoelectric films that are used in common piezoelectric devices and among various candidates, lead zirconate titanate (PZT) is particularly preferred. In addition, the thickness of the target material TG is preferably at least 5 mm for two reasons: first, this provides ease in handling, and secondly, there is no need for frequent replacement with a new target material TG because its surface is less likely to erode and wear on account of sputtering.

In the next step, the interior of the vacuum vessel 12 is evacuated through the gas exhaust pipe 12b by the evacuating means 22 until a predetermined degree of vacuum is created within the vacuum vessel 12, and with the evacuation being continued to maintain the predetermined degree of vacuum, plasma forming gases such as argon gas (Ar) are supplied at predetermined flow rates from the gas supply source 20 through the gas supply pipe 12a. At the same time, the backing plate 14 is supplied with RF power having a power density of at least 4 W/cm2, preferably at least 4.5 W/cm² from the RF power supply 16 to cause an electric discharge from the backing plate 14. As a result, the plasma forming gases introduced into the vacuum vessel 12 form a plasma to generate plasma ions such as Ar ions, whereupon a plasma space is established between the backing plate 14 and the substrate SB.

The positive ions within the thus formed plasma space sputter the target material TG held on the backing plate 14 and the constituent elements in the sputtered target material TG are released from it and deposited, either in a neutral or ionized state, on the substrate SB held on the platform 18, whereupon the process of film deposition starts.

In the film depositing method of the present invention, by supplying the backing plate 14 (the interior of the vacuum vessel 12) with RF power having a power density of at least 4 W/cm², preferably at least 4.5 W/cm² from the RF power supply 16 as described above, thin films can be formed at high deposition rate and, in particular, it becomes possible to control the deposition rate to become at least 3 μm/hr, or at least 3.5 μm/hr.

If the deposition rate is thusly controlled to become at 3 μm/hr or at least 3.5 μm/hr, back sputtering that occurs simultaneously with the formation of a thin film by sputtering and which sputters the thin film being deposited can be suppressed markedly. As a result, particularly in the case of forming a PZT film, there will be no possibility that back sputtering causes Pb to be lost from the film being deposited to thereby change its composition; there is also no possibility that the deposited film will have an unduly strong stress. Thus, thin films can be formed that have superior film characteristics.

While the film depositing method and apparatus according to the present invention have been described above in detail with reference to various embodiments and examples, it should be noted that the present invention is by no means limited to those embodiments and examples and various improvements or design modifications are of course possible without departing from the scope and spirit of the present invention.

### EXAMPLES

On the following pages, the present invention will be described in greater detail by referring to specific examples plus the accompanying drawing. Needless to say, the present invention is by no means limited to the following examples.

### Example 1

As the film depositing apparatus 10 shown in FIG. 1, used was an apparatus of a commercial type (Model CLN 2000 of Oerlikon). The target material TG was a sintered disk of 300 mm diameter with the composition of Pb_{1.1} (Zr_{0.46}Ti_{0.42}Nb_{0.12}) O₃ in a thickness of 5 mm and at a sinter density of 97.5%.

This target material TG was attached to a flat Mo (molybdenum) backing plate of 15 mm thickness by means of In (indium). Molybdenum (Mo) of which the backing plate was made had a thermal expansion coefficient of 4.0×10⁻⁶/° C. whereas the target material TG had a thermal expansion coefficient of 8.0×10⁻⁶/° C.

The distance between the target material TG and the substrate SB was set at 80 mm.

After creating a predetermined vacuum state within the above-described vacuum vessel 12, Ar and O₂ were supplied at respective rates of 80 sccm and 1 sccm until the pressure in the vacuum vessel 12 was 0.8 Pa, and a RF power of 1000 W was supplied to the backing plate from the RF power supply 16 to perform pre-sputtering for 5 hours.

Subsequently, a substrate SB comprising a silicon wafer with an iridium electrode formed on it was placed on the platform 18 and heated to 475° C.; thereafter, a gaseous mixture of Ar and O₂ (2.5%) was introduced into the vacuum vessel 12 and at an internal pressure of 0.8 Pa, a RF power of 3000 W (4.2 W/cm²) was supplied from the RF power supply 16 to perform a 1-hr run of lead zirconate titanate (PZT+Nb) film deposition.

The thickness of the film formed on a surface of the substrate SB was determined with a stylus-type surface profiler and the result was 3.5 μm. Further, examination by XRD (X-ray diffraction) showed that the film had good orientation.

In addition, an upper electrode was formed on the film and its piezoelectric performance was evaluated by d31 measurement with a cantilever; d31 was 250 pm/V, indicating that the film was satisfactory for use as a practical product. Further in addition, the backing plate and the target material TG were examined after the process of film deposition; the target material TG was not cracked or otherwise damaged, and the backing plate was also free from any damage such as peeling.

### Comparative Example 1

A lead zirconate titanate (PZT+Nb) film was deposited by repeating Example 1 under entirely the same conditions, except for using a backing plate having a thermal expansion coefficient of 16×10⁻⁶/° C.

The thickness of the obtained film was measured as in Example 1 and it was 3.5 μm. Further, the film was examined for orientation and piezoelectric performance as in Example 1 and it was found that the film was satisfactory for use as a practical product.

However, a post-deposition examination of the backing plate and the target material TG mounted in the film depositing apparatus revealed that tiny cracks had occurred in the target material TG.

From the foregoing results, it was found that when a film depositing apparatus using a backing plate having a smaller thermal expansion coefficient than that of a target material having a sinter density of at least 95% was employed to perform film deposition with an RF power input of at least 4 W/cm², thin films of good quality could be formed without causing damage to the target material. On the other hand, when a film depositing apparatus using a backing plate having a greater thermal expansion coefficient than that of the target material having a sinter density of at least 95% was employed, cracking occurred in the target, given a RF power input of at least 4 W/cm²; it was thus found that the apparatus, being incapable of depositing films at such high power density, was unsuitable for high-speed film deposition.

### INDUSTRIAL APPLICABIITY

The film depositing apparatus and method of the present invention can be applied to the case of depositing thin films such as a piezoelectric film, an insulator film, and a dielectric film by sputtering and other plasma-assisted vapor-phase deposition techniques; it can thus be applied in depositing thin films such as the piezoelectric films that are used in ink-jet recording heads, ferroelectric memories (FRAMs), and pressure sensors.

### REFERENCE SIGNS LIST

10 film depositing apparatus
12 vacuum vessel
12a gas supply pipe
12b gas exhaust pipe
14 backing plate
16 RF power supply
18 platform
TG target material
SB substrate

1. A film depositing apparatus comprising:
a vacuum vessel;
an evacuating means for evacuating the interior of the vacuum vessel;
a gas supply source for supplying the vacuum vessel with gases necessary for film deposition;
a backing plate that is placed within the vacuum vessel for holding a target formed by sintering;
a substrate holder for holding a deposition substrate within the vacuum vessel in a face-to-face relation with the backing plate; and
a power supply means for supplying electric power between the backing plate and the substrate holder to generate a plasma within the vacuum vessel, wherein the backing plate has a smaller thermal expansion coefficient than that of the target which has a sinter density of at least 95%, the sinter density representing the ratio of the actual weight of a sintered form of the target to its theoretical weight.

2. The apparatus according to claim 1, wherein the power supply means supplies RF power at a power density of at least 4 W/cm².

3. The apparatus according to claim 1, wherein the backing plate is made of a molybdenum-based material.

4. The apparatus according to claim 1, wherein the backing plate has a thickness not smaller than 5 mm but not greater than 30 mm.

5. The apparatus according to claim 1, wherein the target is made of a material for a piezoelectric film that is to be used in a piezoelectric device.

6. The apparatus according to claim 1, wherein the target comprises lead zirconate titanate.

7. The apparatus according to claim 1, wherein the target has a thickness of at least 5 mm.

8. A film depositing method comprising the steps of:
holding a target on a backing plate that is placed within a vacuum vessel and which has a smaller thermal expansion coefficient than that of a target which has a sinter density of at least 95%, the sinter density representing the ratio of the actual weight of a sintered form of the target to its theoretical weight;
placing a deposition substrate held on a substrate holder within the vacuum vessel in a face-to-face relation with the backing plate; and
supplying electric power between the backing plate and the substrate holder, with gases necessary for film deposition being supplied into the vacuum vessel, so as to generate a plasma within the vacuum vessel.

9. The method according to claim 8, wherein RF power having a power density of at least 4 W/cm² is supplied between the backing plate and the substrate holder.

10. The apparatus according to claim 8, wherein the rate of film deposition on the deposition substrate is controlled at 3 μm/hr or more.

11. The method according to claim 8, wherein the target is made of a material for a piezoelectric film that is to be used in a piezoelectric device.

12. The method according to claim 8, wherein the target comprises lead zirconate titanate.

13. The method according to claim 8, wherein the target has a thickness of at least 5 mm.
